(19) United States
(12) Patent Application Publication
(10) Pub. No.: US 2008/0198674 A1
(43) Pub. Date: Aug. 21, 2008

(54) Method of testing an integrated circuit, method of determining defect resistivity changing cells, testing device, and computer program adapted to perform a method for testing an integrated circuit

(76) Inventor: Jan Keller, Fontainebleau (FR)

Correspondence Address: SLATER & MATSIL LLP, 17950 PRESTON ROAD, SUITE 1000, DALLAS, TX, 75252, US

(21) Appl. No.: 11/709,336

(22) Filed: Feb. 21, 2007

(51) Int. Cl. G11C 7/00

(52) U.S. Cl. 365/201; 714/713

(57) ABSTRACT

A method for testing an integrated circuit having an array of resistivity changing cells, wherein the method includes selecting a plurality of cells, setting the state of each selected cell to a defined state, measuring a resistance value being dependent on the resistances of the selected cells, comparing the resistance value with a resistance target value, and classifying the integrated circuit in dependence on the result of the comparison.

### BACKGROUND

The invention generally relates to a method of testing an integrated circuit, a method of determining defect resistivity changing cells, a testing device, and a computer program.

### SUMMARY OF THE INVENTION

According to one embodiment of the present invention, a method of testing an integrated circuit including an array of resistivity changing cells is provided, the method including: selecting a plurality of cells; setting the state of each selected cell to a defined state; measuring a resistance value being dependent on the resistances of the selected cells; comparing the resistance value with a resistance target value; classifying the integrated circuit in dependence on the result of the comparison.

### BRIEF DESCRIPTION OF THE DRAWINGS

For a more complete understanding of the present invention and the advantages thereof, reference is made to the following description taken in conjunction with the accompanying drawings, in which:

FIG. 1 shows a schematic drawing of a processing state of one embodiment of the method according to the present invention;

FIG. 2 shows a schematic drawing of a processing state of one embodiment of the method according to the present invention;

FIG. 3 shows a schematic drawing of a processing state of one embodiment of the method according to the present invention;

FIG. 4 shows a schematic drawing of a processing state of one embodiment of the method according to the present invention;

FIG. 5 shows a schematic drawing of a processing state of one embodiment of the method according to the present invention;

FIG. 6 shows a schematic drawing of a processing state of one embodiment of the method according to the present invention;

FIG. 7 shows a schematic drawing of a processing state of one embodiment of the method according to the present invention;

FIG. 8a shows a schematic cross-sectional view of a first memory state of a CBRAM cell;

FIG. 8b shows shows a schematic cross-sectional view of a second memory state of a CBRAM cell;

FIG. 9 shows a schematic flow chart of one embodiment of the method according to the present invention; and

FIG. 10 shows a schematic flow chart of one embodiment of the method according to the present invention.

### DETAILED DESCRIPTION OF ILLUSTRATIVE EMBODIMENTS

For sake of simplicity, it will be assumed in the following description that the integrated circuit is a resistivity changing memory device, that the resistivity changing cells are resistivity changing memory cells, and that the states of the cells are memory states. However, the present invention is not restricted thereto; the embodiments of the present invention may be applied to arbitrary circuits comprising resistivity changing cells, for example tunable resistors comprising or consisting of resistivity changing cells.

According to one embodiment of the present invention, a method for testing a resistivity changing memory device including an array of memory cells is provided, the method including the following processes: selecting a plurality of memory cells; setting the memory state of each selected memory cell to a defined memory state; measuring a resistance value being dependent on the resistances of the selected memory cells; comparing the resistance value with a resistance target value; classifying the memory device in dependence on the result of the comparison.

According to one embodiment of the present invention, all selected memory cells are set to the same memory state (“common memory state”). However, the present invention is not restricted thereto, arbitrary memory state patterns may be used. For example, the memory states of a row of memory cells may alternate between memory state “0” and memory state “1”.

According to one embodiment of the present invention, the memory state of a plurality of memory cells is collectively measured, but not successively measured memory state for memory state. For example, sensing currents may be simultaneously routed through all memory cells set to a defined memory state. According to one embodiment of the present invention, only the sum of all sensing currents is measured, i.e., not each sensing current individually.

All selectable memory cells of the resistivity changing memory device may be selected at once. Alternatively, it is also possible to select only a part of the selectable memory cells.

The plurality of memory cells selected may define a continuous memory cell area. The invention, however, is not restricted to this; it is also possible to select a plurality of memory cells not defining a continuous memory cell area. For example, it may be possible to select each second memory cell of a column and of a row of the memory cell array such that selected memory cells and unselected memory cells alternate with each other (chequerboard pattern). Arbitrary selection patterns are possible.

Generally, “defined memory state” and “common memory state” may be arbitrary memory states (e.g., “0”, “1” or even further memory states) which can be adopted by the memory cells. According to one embodiment of the present invention, the common memory state/defined memory state is the memory state which shows the highest resistance (compared to the rest of possible memory states). For example, all memory cells selected may be set to the “OFF” memory state.

It has been recognized by the inventors that the present invention works best if all selected memory cells (i.e., the memory cells which are tested) are set to the memory state which has the highest possible resistance. More generally, the higher the difference between the resistance of the non-defect memory cells and the resistance of the defect memory cells are (defect memory cells usually show the lowest possible resistance), the better the present invention works since the strength of reflection of the defect memory cells within the sensing signal (voltage signal or current signal) is proportional to this resistance difference. Therefore, according to one embodiment of the present invention, the selected memory cells have to be set into such resistive memory states that the resulting difference between the resistance of the non-defect memory cells and the resistance of the defect memory cells effects a corresponding reflection within the sensing signal strong enough to be detected.

To give an example, it is assumed in the following description that a solid electrolyte memory cell array having 64 memory cells is tested. Here, the resistance value for a memory cell set to the memory state having the highest possible resistance is 1 MOhm (Roff state), and the resistance value for a memory cell set to the memory state having the lowest possible resistance is 10 kOhm (Ron state). If all memory cells are set to the Roff state, a resistance of 16 kOhm (1/Rtotal=64*1/Roff; Rtotal˜16 kOhm) results if the memory cells are connected in parallel. This is true for a memory cell array in which all memory cells are non-defect memory cells. If one single memory cell does not switch to the Roff state, it has a resistance of 10 kOhm or less (in case of a real short circuit). Since Ron<Rtotal (Rtotal for perfect memory cell array), it can be immediately seen from a resistance measuring process that at least one memory cell shows a short circuit. In order to ensure that this measurment technique works, Rtotal be>Ron, wherein 1/Rtotal=x*1/Roff, and wherein x is the number of memory cells, and wherein Rtotal is to be understood in the context of an array of non-defect memory cells which are connected in parallel. The present invention is not limited to the resistance values of this example. For example, the Roff resistance values may be significantly larger.

The resistivity changing memory device may, for example, be a solid electrolyte random access memory device, also known as conductive bridging random access memory device (CBRAM), a magneto-resistive random access memory device (MRAM), a phase changing random access memory device (PCRAM), an organic random access memory (ORAM) device, or the like. However, the present invention is not restricted to these types of memory devices.

The testing method according to the embodiments presented above is capable of checking very fast whether an array of memory cells or a particular area thereof has one or several defect memory cells. However, it is not possible to locate the exact position of the defect memory cell.

Therefore, according to one embodiment of the present invention, a method of determining defect memory cells within a memory cell array of a resistivity changing memory device is provided, including the following processes: a) setting a group of memory cells to a defined memory state, b) splitting the group of memory cells into at least two memory cell subgroups, c) starting a process of successively measuring a subgroup resistance value for each memory cell subgroup, each subgroup resistance value being dependent on the resistances of the memory cells of the respective memory cell subgroup, d) comparing the measured subgroup resistance values with corresponding subgroup resistance target values, e) when a measured subgroup resistance value does not match the corresponding subgroup resistance target value: splitting the memory cell subgroup not matching the subgroup resistance target value into at least two further subgroups, and repeating processes c) to e) for the further subgroups.

According to one embodiment of the present invention, the processes c) to e) are repeated as long as a defect memory cell has been located.

According to one embodiment of the present invention, each subgroup resistance value measured is the sum of the individual memory cell resistances of the memory cells of the corresponding memory cell subgroup.

According to one embodiment of the present invention, the memory cells are connected in parallel. In this case, the term “sum of the individual memory cell resistances” means the inverse sum of the resistances of the single memory cell. Assuming that the resistances of the single memory cells are R1, R2, R3, . . . , the sum S of the individual memory cell resistances is given by: 1/S=1/R1+1/R2+1/R3+ . . . .

All embodiments discussed in conjunction with the memory device testing method may also be applied to the embodiments of the defect memory cell determining method, as, for example, indicated by the following embodiments. According to one embodiment of the present invention, each process of measuring a subgroup resistance value is carried out by simultaneously routing respective sensing currents through all memory cells of the respective memory cell subgroup. According to one embodiment of the present invention, the group of memory cells includes all memory cells of the resistivity changing memory device. According to one embodiment of the present invention, the memory state of each memory cell of the group of memory cells is set to a common memory state. According to one embodiment of the present invention, the resistivity changing memory device is a CBRAM device, a MRAM device, a PCRAM device or an ORAM device.

According to one embodiment of the present invention, a testing device for testing a resistivity changing memory device including an array of memory cells is provided, the testing device including: selecting means selecting a plurality of memory cells; setting means setting the memory state of each selected memory cell to a defined memory state; measuring means measuring a resistance value being dependent on the resistances of the selected memory cells; comparison means comparing the resistance value with a resistance target value; classifying means classifying the memory device in dependence on the result of the comparison.

According to one embodiment of the present invention, the selecting means is further configured to setting a group of memory cells to a defined memory state and splitting the group of memory cells into at least two memory cell subgroups.

According to one embodiment of the present invention the measuring means is further configured to start a process of successively measuring a subgroup resistance value for each memory cell subgroup, each subgroup resistance value being dependent on the resistances of the memory cells of the respective memory cell subgroup.

According to one embodiment of the present invention, the comparison means is further configured to compare the measured subgroup resistance values with corresponding subgroup resistance target values.

According to one embodiment of the present invention, the decision means is further configured to decide, when a measured subgroup resistance value does not match the corresponding subgroup resistance target value splitting the memory cell subgroup not matching the subgroup resistance target value into at least two further subgroups.

According to one embodiment of the present invention, the setting means is further configured to set the memory state of each selected memory cell to a common memory state.

According to one embodiment of the present invention, the resistivity changing memory device is a CBRAM device, a MRAM device, a PCRAM device or an ORAM device.

According to one embodiment of the present invention, the common memory state is the OFF memory state.

The resistivity changing memory device may for example be a solid electrolyte random access memory device, also known as conductive bridging random access memory device (CBRAM), a magneto-resistive random access memory device (MRAM), a phase changing random access memory device (PCRAM), or the like. However, the present invention is not restricted to these types of memory devices.

According to one embodiment of the present invention, a computer program is provided adapted to perform, when being executed on a computing device or a digital signal processor, a method for testing a resistivity changing memory device including an array of memory cells, the method including the following processes: selecting a plurality of memory cells; setting the memory state of each selected memory cell to a defined memory state; measuring a resistance value being dependent on the resistances of the selected memory cells; comparing the resistance value with a resistance target value; classifying the memory device in dependence on the result of the comparison.

According to one embodiment of the present invention, a computer program is provided adapted to perform, when being executed on a computing device or a digital signal processor, a method for determining a defect memory cell within a memory cell array of a resistivity changing memory device, including the following processes: a) setting a group of memory cells to a defined memory state, b) splitting the group of memory cells into at least two memory cell subgroups, c) starting a process of successively measuring a subgroup resistance value for each memory cell subgroup, each subgroup resistance value being dependent on the resistances of the memory cells of the respective memory cell subgroup, d) comparing the measured subgroup resistance values with corresponding subgroup resistance target values, e) when a measured subgroup resistance value does not match the corresponding subgroup resistance target value splitting the memory cell subgroup not matching the subgroup resistance target value into at least two further subgroups, and repeating processes c) to e) for the further subgroups.

An embodiment of the present invention provides a data carrier storing computer programs as discussed above.

Memory devices having high memory densities are usually subjected to memory device testing procedures, for example, after having finished a memory device fabrication process, or during a booting process of a computing device like a mobile phone, a handheld, a personal computer, etc., which includes memory devices. According to one embodiment of the present invention, the efficiency of memory device testing procedures can be improved.

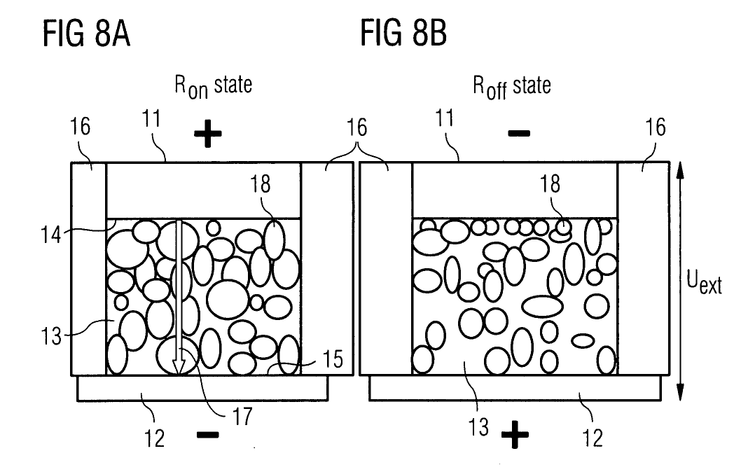

An embodiment of the present invention is applicable to resistivity changing memory devices. Therefore, in the following description, making reference to FIGS. 8a and 8b, a basic principle underlying CBRAM devices (as an example of a resistivity changing memory device) will be explained.

As shown in FIG. 8a, a CBRAM cell includes a first electrode 11, a second electrode 12, and a solid electrolyte block 13 sandwiched between the first electrode 11 and the second electrode 12. The first electrode 11 contacts a first surface 14 of the solid electrolyte block 13, the second electrode 12 contacts a second surface 15 of the solid electrolyte block 13. The solid electrolyte block 13 is isolated against its environment by an isolation structure 16. The first surface 14 usually is the top surface, the second surface 15 the bottom surface of the solid electrolyte block 13. In the same way, the first electrode 11 generally is the top electrode, and the second electrode 12 the bottom electrode of the CBRAM cell. One of the first electrode 11 and the second electrode 12 is a reactive electrode, the other one an inert electrode. Here, the first electrode 11 is the reactive electrode, and the second electrode 12 is the inert electrode. In this example, the first electrode 11 includes silver (Ag), the solid electrolyte block 13 includes silver-doped chalcogenide material, and the isolation structure 16 includes silicon oxide (SiO₂).

If a voltage as indicated in FIG. 8a is applied across the solid electrolyte block 13, a redox reaction is initiated which drives Ag⁺ ions out of the first electrode 11 into the solid electrolyte block 13 where they are reduced to Ag, thereby forming Ag rich clusters within the solid electrolyte block 13. If the voltage applied across the solid electrolyte block 13 is applied for a long period of time, the size and the number of Ag rich clusters within the solid electrolyte block 13 is increased to such an extent that a conductive bridge 17 between the first electrode 1 and the second electrode 12 is formed. In case that a voltage is applied across the solid electrolyte block 13 as shown in FIG. 8b (inverse voltage compared to the voltage applied in FIG. 8a), a redox reaction is initiated which drives Ag⁺ ions out of the solid electrolyte block 13 into the first electrode 11 where they are reduced to Ag. As a consequence, the size and the number of Ag rich clusters within the solid electrolyte block 13 is reduced, thereby erasing the conductive bridge 17.

In order to determine the current memory status of a CBRAM cell, a sensing current is routed through the CBRAM cell. The sensing current experiences a high resistance in case no conductive bridge 17 exists within the CBRAM cell, and experiences a low resistance in case a conductive bridge 17 exists within the CBRAM cell. A high resistance may for example represent “0”, whereas a low resistance represents “1”, or vice versa.

Memory devices as described in conjunction with FIGS. 8a and 8b usually comprise an array of memory cells, each memory cell being adapted to store one or more bits of information. As already indicated, resistive memory devices store information by changing the resistance of the active material (for example, the solid electrolyte block in a CBRAM device) within the memory cell. A high resistance of the active material may, for example, mean “1”, a low resistance of the active material “0”. This means that the resistance of the active material corresponding to the memory state “1” is kept within a defined resistance tolerance range. The same applies for the memory state “0”. If the resistance of the active material lies outside of these resistant ranges (for example if the resistance of the active material lies in the middle between the high resistance and the low resistance), the memory state of the memory cell cannot be identified. Therefore, usually each memory cell of the memory cell array is individually tested. However, testing each memory cell of a memory cell area including a large amount of memory cells is time consuming and therefore costly.

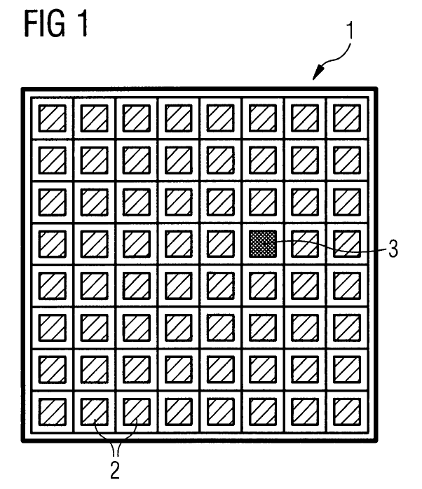

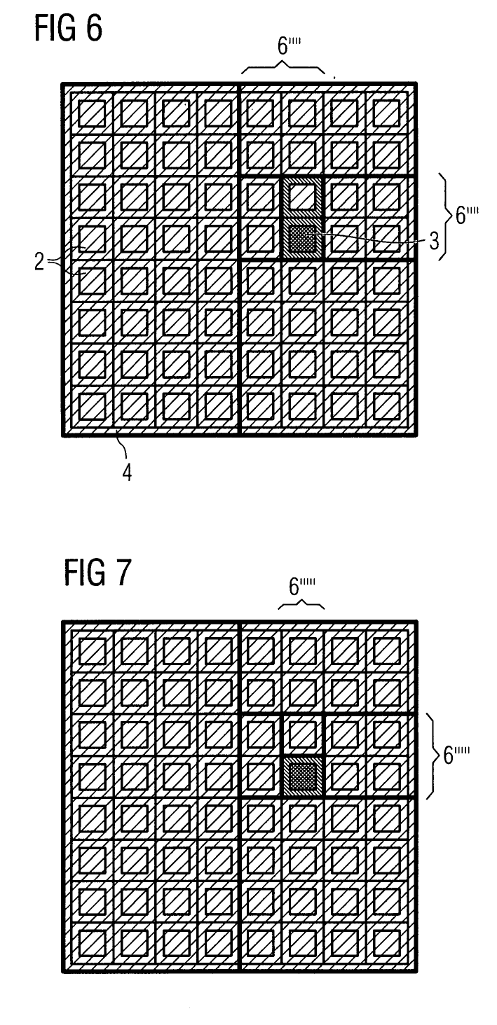

In the following description, one embodiment of the testing method according to the present invention will be explained with reference to FIGS. 1 to 7.

FIG. 1 shows a memory cell array 1 including a plurality of programmable memory cells 2 arranged in rows and columns (it should be noted that the present invention is not restricted to a memory cell array arranged in rows and columns; the present invention can be applied to arbitrary memory cell array architectures). In this example, the memory cell array I includes one defect memory cell 3. All other memory cells 2 are not defect, i.e., work as intended. The position of the defect memory cell 3 is not known.

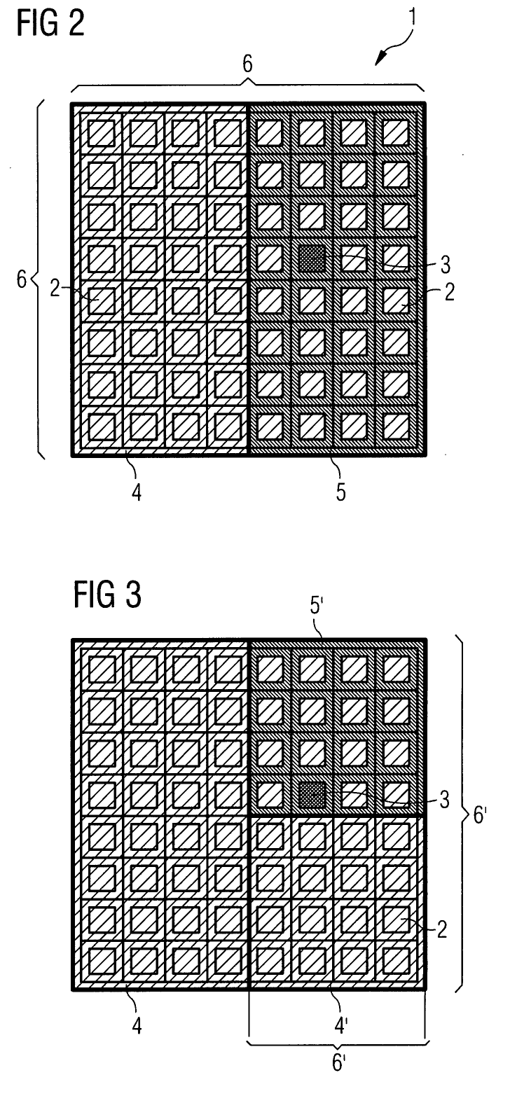

In order to find out whether the memory cell array 1 as a whole works correctly, all memory cells 2 including the defect memory cell 3 are selected and set into the same memory state (common memory state). For example, all memory cells are set to the memory state showing the highest resistance (usually “OFF” memory state). Then the sum of all individual memory cell resistances of the memory cells 2 is determined. Since each memory cell 2 has been set to the same memory state, each individual cell resistance should have the same memory cell resistance value. Now, the sum of individual memory cell resistances of all memory cells 2 set to the common memory state are measured. The measurement process can, for example, be performed by measuring all individual memory cell resistances at the same time. Alternatively, it may, for example, be possible to divide the memory cell array 1 into several memory cell groups, and successively measuring all individual memory cell resistances of the memory cells of one memory cell group. Since the defect memory cell 3 shows a different individual memory cell resistance compared to the other memory cells 2, the measured sum of individual memory cell resistances does not match the resistance target value determined before. Thus, it is already known at this point of time that the memory cell array 1 has at least one defect memory cell without having successively tested each memory cell 2 individually. If there is no chance of repairing the defect memory cell 3 or if it is not possible to use the memory cell array 1 in case one or several memory cells 2 are defect, the testing method can be terminated at this stage, and the defect memory cell array 1 is discarded. If, however, there is a need of locating the position of the defect memory cell 3, the testing method will continue with the following processes (as shown in FIG. 2).

A first memory cell working group 6 is defined including all memory cells 2 set to a defined memory state.

The memory cells 2 of the first memory cell working group 6 are split into at least two memory cell subgroups, in this example into a first memory cell subgroup 4 and a second memory cell subgroup 5 having the same amount of memory cells 2, respectively. The first memory cell subgroup 4 and the second memory cell subgroup 5 may also include different amounts of memory cells 2. The second memory cell subgroup 5 includes the defect memory cell 3.

A subgroup resistance target value is determined for each memory cell subgroup 4 and 5. This means that a first subgroup resistance target value is determined indicating the target sum of the individual memory cell resistances of all memory cells included within the first memory cell subgroup 4. The same is carried out for the second memory cell subgroup 5. Since the amount of memory cells within each memory cell subgroup 4 and 5 is the same, the subgroup resistance target value is the same for the first memory cell subgroup 4 and the second memory cell subgroup 5. The embodiment of the invention is not restricted to this. If the number of memory cells included within the first memory cell subgroup 4 is not the same as the number of memory cells included within the second memory cell subgroup 5, corresponding subgroup resistant target values differ from each other.

A process is started which successively measures the subgroup resistance values of all memory cell subgroups, i.e., for example, the first subgroup resistance value (i.e. the resistance value for the first memory cell subgroup 4) is measured. Since the first subgroup resistance value measured matches a corresponding first subgroup resistance target value, it is determined that all memory cells included within the first memory cell subgroup 4 work as intended. This, however, means that the defect memory cell has to be a memory cell included within the second memory cell subgroup 5.

In order to more clearly locate the position of the defect memory cell 3, the second memory cell subgroup 5 is defined to become a second memory cell working group 6′. As shown in FIG. 3, the memory cell working group 6′ is split into a first memory cell subgroup 4′ and a second memory cell subgroup 5′. It is also possible to split the memory cell group working 6 into more than two memory cell subgroups. For each of the first and the second memory cell subgroup 4′, 5′, a corresponding subgroup resistance target value concerning the sum of the individual memory cell resistances of all memory cells of the respective memory cell subgroups 4′ and 5′ is determined. Then, the subgroup resistance value of one of the first and second memory cell subgroups 4′ and 5′ is measured and compared with the corresponding subgroup resistance target value. Since all memory cells 2 included within the first memory cell subgroup 4′ work as intended, the measured subgroup resistance value matches the subgroup resistance target value. As a consequence, the defect memory cell 3 has to be one of the memory cells 2 included within the second memory cell subgroup 5′.

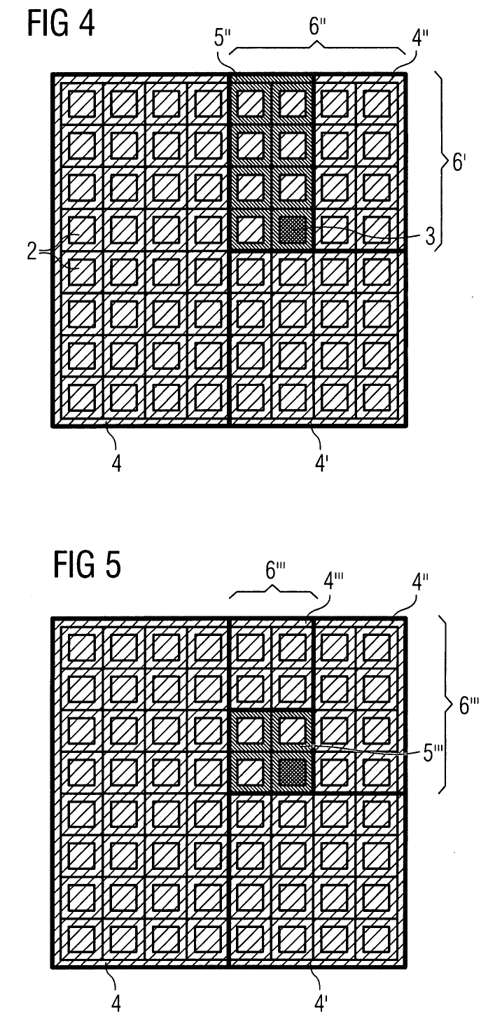

In order to more clearly define the location of the defect memory cell 3, the second memory cell subgroup 5′ is defined to become a third memory cell working group 6″ as shown in FIG. 4. The memory cell working group 6″ is divided into a first memory cell subgroup 4″ and a second memory cell subgroup 5″. A subgroup resistance target value is determined for the first and the second memory cell subgroup 4″ and 5″, respectively, each subgroup resistance target value concerning the sum of the individual memory cell resistances of all memory cells of the respective memory cell subgroup. Then, for example, the subgroup resistance target value of the second memory cell subgroup 5″ is measured. Since the measured subgroup resistance value does not match the corresponding subgroup resistance target value, it is determined that the defect memory cell 3 lies within the second memory cell subgroup 5″.

As a consequence, as can be taken from FIG. 5, the second memory cell subgroup 5″ is defined to become the new (fourth) memory cell working group 6′″. The iterative procedure as indicated above is repeated until the defect memory cell 3 has been located, as shown in FIG. 7.

In the embodiment shown within the FIGS. 1 to 7, it has been assumed that the memory states of all memory cells selected are set to the same memory state (common memory state). According to one embodiment of the present invention, the common memory state is the state having the highest possible resistance. In case that the memory cells are multi level memory cells (the possible memory states of each memory cell is higher than two), the common memory state may also be a memory state not having the highest resistance, but having a higher resistance than the lowest possible resistance.

Further, in the embodiment shown within the FIGS. 1 to 7, it has been assumed that the memory cell subgroups into which a group of memory cells are divided has the same number of memory cells. The present invention, however, is not restricted thereto, i.e., the memory cell subgroups into which a group of memory cells (memory cell working group) are divided may have different numbers of memory cells, respectively.

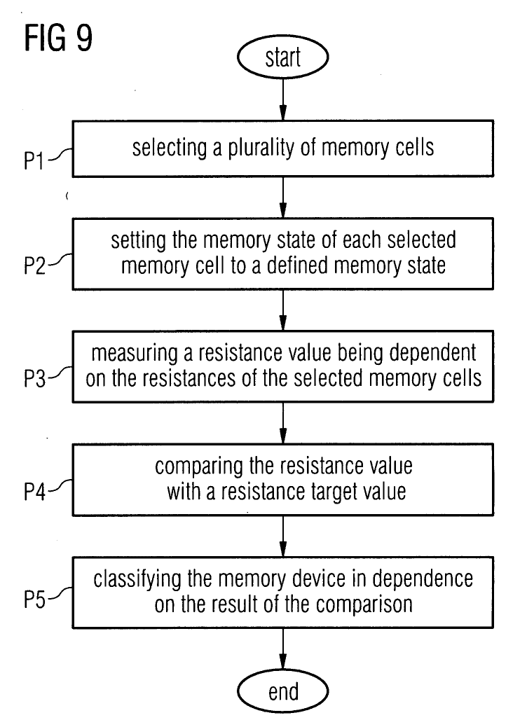

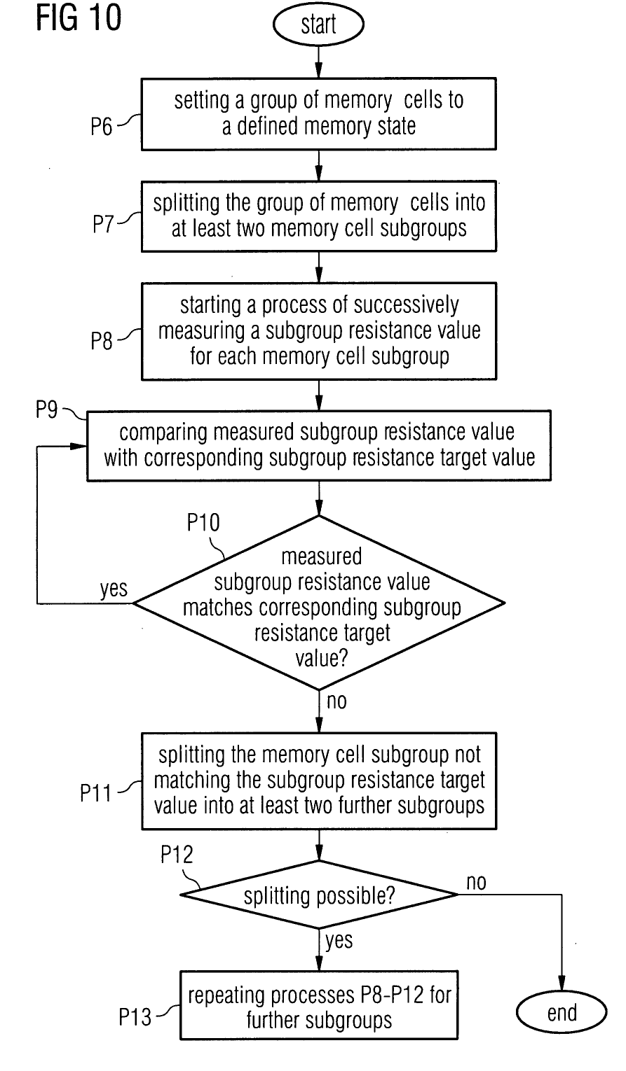

FIG. 9 shows a schematic flow chart of one embodiment of the method of testing a resistive memory device comprising an array of memory cells according to the present invention.

In a first process P1, a plurality of memory cells are selected. In a second process P2, the memory state of each selected memory cell is set to a defined memory state. In a third process P3, a resistance value being dependent on the resistances of the selected memory cells is measured. In a fourth process P4, the resistance value is compared with a resistance target value. In a fifth process P5, the memory device is classified in dependence on the result of the comparison.

FIG. 10 shows a schematic flow chart of one embodiment of the method of determining a defect memory cell in a resistive memory device comprising an array of memory cells according to an embodiment of the present invention.

In a first process P6, a group of memory cells is set to a defined memory state. In a second process P7, the group of memory cells is split into at least two memory cell subgroups. In a third process P8, a process of successively measuring a subgroup resistance value for each memory cell subgroup is started, each subgroup resistance value being dependent on the resistances of the memory cells of the respective memory cell subgroup. In a fourth process P9, the measured subgroup resistance value is compared with corresponding subgroup resistance target values. In a fifth process P10, it is determined whether a measured subgroup resistance value does match the corresponding subgroup resistance target value. If this is not the case, the memory cell subgroup not matching the subgroup resistance target value is split into at least two further subgroups in a sixth process P11. If this is not possible (determined in a seventh process P12), a defective memory cell has already be detected, and the method is terminated. If it is possible, then in an eighth process P13 the third to seventh processes P8 to P12 are repeated for the further subgroups (as long as a defective memory cell has been detected).

In the following description, further aspects of an embodiment of the present invention will be explained.

In normal testing procedures, all cells have to be tested (time consuming). Alternatively, a test pattern has to be compared to reference array (space consuming).

According to an embodiment of the present invention, by applying the test pattern described below, only subarrays of the whole cell array have to be tested for the OFF state. This embodiment saves test time or makes the reference array for the OFF test unnecessary. In particular, it offers a fast and easy way to perform a first test for repairability before testing every cell for proper function.

Test pattern: Switch all cells to defined OFF state. Test all cells for OFF state (resistance). Because of the high resistance of the cells in the OFF state, failing cells drastically change the array resistance which makes it easy to detect a fail. The array is divided in two subarrays, which are separately tested for the OFF state. The failing subarray is divided into two subarrays again which are tested separately. By continuing this method, the number of cells which are remaining is divided by two and one is able to detect a failing cell after n=2 log₂ N processess (N number of cells in array) for N=2^{x} (x being an integer). If every single cell has to be tested, one needs in the worst case N processes to detect the failing cells of a reference array has to be used.

An example for an array consisting of N=64 cells (see FIGS. 1 to 7): Test full array, test fails. Test left half of array, pass. Test left half of array, test fails, 32 cells remaining. Test upper half of left subarray, pass. Test lower half of remaining. Test upper half of left subarray, pass. Test lower half of subarray, fail, 16 cells remaining. Test left half of subarray, pass. Test right half of subarray, fail, 8 cells remaining. Test upper half of left subarray, pass. Test lower half of subarray, fail, 4 cells remaining. Test left half of subarray, pass. Test right half of subarray, fail, 2 cells remaining. Test upper half of left subarray, pass. Failing cell remaining.

Examples for possible implementation includes: in MEM/Booottest in application (safe time and space) and fast way to test for repairability in functional test.

As has become apparent in the forgoing description, the testing method according to an embodiment of the present invention has the following advantages: since the number of test processes normally needed when successively testing each memory cell individually grows with the number of memory cells, a lot of time is needed in conventional testing methods in order to test a memory cell array having a large amount of memory cells. The present invention avoids this time consuming testing by testing a plurality of memory cells at the same time. Further, it is possible to safe space on a memory device including the memory cell array since the testing method according to the present invention does not need any reference array for testing the memory device.

The embodiments of the method according to the present invention may be applied to test arbitrary resistive memory devices like memory devices of mobile phones, handhelds, personal computers, etc.

The testing method according to an embodiment of the present invention may, for example, be implemented as testing software running within a computing device (like a personal computer) during the booting procedure of the computing device (for example, during a memory self test during the booting procedure of a personal computer). Further, the testing software can be implemented within testing devices used by memory device manufacturers in order to test memory devices fabricated.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined solely by the claims appended hereto.

What is claimed is:

1. A method of testing an integrated circuit comprising an array of resistivity changing cells, the method comprising:
selecting a plurality of cells;
setting the state of each selected cell to a defined state;
measuring a resistance value that is dependent on resistances of the selected cells;
comparing the resistance value with a resistance target value; and
classifying the integrated circuit depending upon the result of the comparison.

2. The method according to claim 1, wherein the resistance value measured is the sum of individual cell resistances of all cells set to a defined state.

3. The method according to claim 1, wherein measuring the resistance value comprises simultaneously routing respective sensing currents through all cells set to a defined state.

4. The method according to claim 1, wherein selecting a plurality of cells comprises selecting all selectable cells of the integrated circuit.

5. The method according to claim 1, wherein setting the state of each selected cell comprises setting the state of each selected cell to a common state.

6. The method according to claim 1, wherein the cells comprise resistivity changing memory cells.

7. The method according to claim 6, wherein the integrated circuit comprises a solid electrolyte random access memory (CBRAM) device.

8. The method according to claim 6, wherein the integrated circuit comprises a magneto-resistive random access memory (MRAM) device.

9. The method according to claim 6, wherein the integrated circuit comprises a phase changing random access memory (PCRAM) device.

10. The method according to claim 6, wherein the integrated circuit comprises an organic random access memory (ORAM) device.

11. A method of determining defective resistivity changing cells within a cell array of an integrated circuit, the method comprising:
a) setting a group of cells to a defined state;
b) splitting the group of cells into at least two cell subgroups;
c) starting a process of successively measuring a subgroup resistance value for each cell subgroup, each subgroup resistance value being dependent on resistances of the cells of the respective cell subgroup;
d) comparing the measured subgroup resistance values with corresponding subgroup resistance target values; and
e) when a measured subgroup resistance value does not match the corresponding subgroup resistance target value:
splitting the cell subgroup not matching the subgroup resistance target value into at least two further subgroups; and
repeating processes c) to e) for the further subgroups.

12. The method according to claim 1l, wherein the processes c) to e) are repeated as long as a defect cell has been located.

13. The method according to claim 11, wherein each subgroup resistance value measured is the sum of the individual cell resistances of the cells of the corresponding cell subgroup.

14. The method according to claim 11, wherein measuring a subgroup resistance value comprises simultaneously routing respective sensing currents through all cells of the respective cell subgroup.

15. The method according to claim 11, wherein the group of cells includes all cells of the resistivity changing device.

16. The method according to claim 11, wherein setting a group of cells to a defined state comprises setting each cell of the group of cells to a common state.

17. The method according to claim 11, wherein the cells comprise resistivity changing memory cells.

18. The method according to claim 17, wherein the integrated circuit comprises a CBRAM device, a MRAM device, a PCRAM device or an ORAM device.

19. A testing device for testing an integrated circuit comprising an array of resistivity changing cells, the testing device comprising:
selecting means for selecting a plurality of cells;
setting means for setting the state of each selected cell to a defined state;
measuring means for measuring a resistance value that is dependent on the resistances of the selected cells;
comparison means for comparing the resistance value with a resistance target value; and
classifying means for classifying the integrated circuit in dependance on the result of the comparison.

20. The testing device according to claim 19, wherein the selecting means is further configured to set a group of cells to a defined state and split the group of cells into at least two cell subgroups.

21. The testing device according to claim 20, wherein the measuring means is further configured to start a process of successively measuring a subgroup resistance value for each cell subgroup, each subgroup resistance value being dependent on the resistances of the cells of the respective cell subgroup.

22. The testing device according to claim 21, wherein the comparison means is further configured to compare the measured subgroup resistance values with corresponding subgroup resistance target values.

23. The testing device according to claim 22, further comprising decision means for deciding, when a measured subgroup resistance value does not match the corresponding subgroup resistance target value, that the cell subgroup not matching the subgroup resistance target value should be split into at least two further subgroups.

24. The testing device according to claim 21, wherein the setting means is further configured to set the state of each selected cell to a common state.

25. The testing device according to claim 21, wherein the cells comprise resistivity changing memory cells.

26. The testing device according to claim 25, wherein the integrated circuit comprises a CBRAM device, a MRAM device, a PCRAM device or an ORAM device.

27. A computer program adapted to perform, when being executed on a computing device or a digital signal processor, a method for testing an integrated circuit comprising an array of resistivity changing cells, the method comprising:
selecting a plurality of cells;
setting the state of each selected cell to a defined state;
measuring a resistance value being dependent on the resistances of the selected cells;
comparing the resistance value with a resistance target value; and
classifying the device in dependence on the result of the comparison.

28. A data carrier storing a computer program according to claim 27.

29. A computer program adapted to perform, when being executed on a computing device or a digital signal processor, a method for determining a defect cell within a resistivity changing cell array of an integrated circuit, comprising the following processes:
a) setting a group of cells to a defined state;
b) splitting the group of cells into at least two cell subgroups;
c) starting a process of successively measuring a subgroup resistance value for each cell subgroup, each subgroup resistance value being dependent on the resistances of the cells of the respective cell subgroup;
d) comparing the measured subgroup resistance values with corresponding subgroup resistance target values; and
e) when a measured subgroup resistance value does not match the corresponding subgroup resistance target value:
splitting the cell subgroup not matching the subgroup resistance target value into at least two further subgroups; and
repeating processes b) to e) for the further subgroups.

30. A data carrier storing a computer program according to claim 29.
